(19) United States
(12) Patent Application Publication
(10) Pub. No.: US 2015/0030985 A1
(43) Pub. Date: Jan. 29, 2015

(54) Multiphoton Curing Methods Using Negative Contrast Compositions

(71) Applicants: Robert J. DEVOE, Saint Paul, MN (US); Tzu-Chen LEE, Saint Paul, MN (US); Brian J. GATES, Saint Paul, MN (US); 3M INNOVATIVE PROPERTIES COMPANY, St. Paul, MN (US)

(72) Inventors: Robert J. DeVoe, Mahtomedi, MN (US); Tzu-Chen Lee, Woodbury, MN (US); Brian J. Gates, Osceola, WI (US)

(21) Appl. No.: 14/378,577

(22) PCT Filed: Feb. 18, 2013
(86) PCT No.: PCT/US13/26585

§ 371 Date: Aug. 13, 2014

Related U.S. Application Data
(60) Provisional application No. 61/604,135, filed on Feb. 28, 2012.

(51) Int. Cl. G03F 7/20

(52) U.S. Cl. CPC G03F 7/2053
USPC 430/325; 430/322

(57) ABSTRACT

The present disclosure relates to multiphoton absorption methods for curing a photocurable composition under conditions wherein negative contrast occurs. The photocurable composition includes a free-radically polymerizable compound. The method is applicable to fabrication of structures with micron-scale dimensions or less.

### FIELD

The present disclosure broadly relates to methods and materials for multiphoton-induced photocuring.

### BACKGROUND

In typical multiphoton processes used to fabricate two-dimensional (2-D) and/or three-dimensional (3-D) structures with micron-scale or submicron-scale resolution, a photocurable composition is selectively cured using high-intensity light (e.g., near infrared light as provided by, for example, a near infrared (NIR) laser).

In many known implementations, the photocurable composition includes one or more free-radically polymerizable compounds (e.g., acrylates and/or methacrylates). The photocurable composition is not generally sensitive to light with near infrared wavelengths, but can be cured through non-linear simultaneous multiphoton absorption of the light by a multiphoton photoinitiator system included in the photocurable material. Through this process, energy equivalent to approximately twice that of the light used is absorbed by the multiphoton photoinitiator system, which decomposes to generate free-radicals that initiate free-radical polymerization (typically with cross-linking) of the free-radically polymerizable compound(s) included in the photocurable composition. Accordingly, at least partial curing of the photocurable composition occurs proximate the focus of the laser beam. The focus of the light is directed to different regions within the photocurable composition resulting in latent structures formed within the photocurable composition. Subsequent removal of insufficiently cured regions of the photocurable composition (e.g., by solvent development) produces the corresponding actual structures.

Because multiphoton absorption resulting in curing (e.g., free-radical polymerization) is highly dependent on intensity and dosage of the light used, it is possible to fabricate very small (e.g., micron-scale or nanometer-scale) polymerized volume elements (commonly termed “voxels”, which is shorthand for volume pixels). Typically, the focal point of a laser beam is approximately ellipsoidal, with an intensity profile that is roughly Gaussian along any diameter. Accordingly, typical voxels generated by exposure to a laser beam are roughly spherical, or may be similar to an elongated sphere, where the elongation is along one or more than one axis (e.g., x-axis, y-axis, or z-axis).

Through repetition, voxel by voxel, larger nanostructures and microstructures can be constructed by controlling the position of the focus of the laser beam in three dimensions (i.e., x-axis, y-axis, and z-axis directions) relative to the resin. In many cases, 3-D structures are formed by curing approximately single voxel layers (e.g., in the x-y plane), followed by moving the focal point about one voxel length (e.g., in the z-axis), and curing a subsequent layer (e.g., in the x-y plane). This process may be repeated until a desired structure is formed, and then realized through a developing step (e.g., as discussed above).

### SUMMARY

There is a continuing need for systems and methods which can enable photolithographic fabrication of high resolution microstructures and nanostructures that have increasingly small dimensions. We have discovered methods of achieving the foregoing using free-radically polymerizable materials under various conditions of negative contrast (i.e., an incremental increase in light exposure causes a decrease in curing).

In one aspect, the present disclosure provides a method comprising the steps:

a) providing a beam of light, wherein the beam of light has a cross-sectional beam profile comprising an inner region having a relatively lower intensity of the light bounded by an outer region having a relatively higher intensity of the light, and wherein the inner region and the outer region have the same temporal profile;

b) providing a photocurable composition, wherein the photocurable composition comprises a free-radically polymerizable compound, a free-radical polymerization inhibitor, and a multiphoton photoinitiator system;

c) exposing at least a portion of the photocurable composition to the beam of light such that multiphoton absorption of a portion of the light by the multiphoton photoinitiator system initiates free-radical polymerization of at least a portion of the free-radically polymerizable compound, wherein irradiating the photocurable composition with at least a portion of the inner region of the beam of light causes curing of a portion of the photocurable composition to at least a threshold level for developing, and wherein irradiating the photocurable composition with at least a portion of the outer region of the beam of light adjacent to the inner region does not cause curing of the photocurable composition to at least the threshold level for developing.

In some embodiments, the photocurable composition further comprises an organic polymer that is substantially nonflowable. In some embodiments, the outer region of the cross-sectional beam profile is substantially annular. In some embodiments, the beam of light comprises a laser beam in a Gauss-Laguerre mode. In some embodiments, the photocurable composition forms a layer disposed on a substrate. In some embodiments, the method further comprises developing at least a portion of the photocurable composition that is cured (e.g., polymerized and/or crosslinked) to at least the threshold level for developing in step c). In some embodiments, the free-radical polymerization inhibitor comprises an organic free-radical polymerization inhibitor. In some embodiments, the free-radically polymerizable compound comprises at least two acryloyl groups.

In another aspect, the present disclosure provides a method comprising the steps:

a) providing at least one beam of light;

b) providing a photocurable composition, wherein the photocurable composition comprises a free-radically polymerizable compound, a free-radical polymerization inhibitor other than molecular oxygen, and a multiphoton photoinitiator system, wherein the free-radical polymerization inhibitor is effective in the absence of oxygen;

c) curing a portion of the photocurable composition by exposing it to the at least one beam of light such that multiphoton absorption of a portion of the light by the multiphoton photoinitiator system initiates free-radical polymerization of the free-radically polymerizable compound, and such that incrementally increasing exposure to the beam of light causes less curing of at least a portion of the photocurable composition exposed to the beam of light, wherein the photocurable composition is substantially free of molecular oxygen prior to said exposing the photocurable composition to the beam of light.

In some embodiments, the free-radically polymerizable compound comprises at least two methacryloyl groups, and the photocurable composition is substantially free of free-radically polymerizable acrylates. In some embodiments, the photocurable composition further comprises an organic polymer, and is substantially nonflowable. In some embodiments, the photocurable composition forms a layer disposed on a substrate. In some embodiments, petition the beam of light is focused at a different location within the photocurable composition according to a predetermined pattern.

In another aspect, the present disclosure provides a method comprising the steps:

a) providing a beam of light;

b) providing a photocurable composition, wherein the photocurable composition comprises:
a free-radically polymerizable compound,
a Type I photoinitiator, and
a free-radical polymerization inhibitor;

c) at least partially curing at least a portion of the photocurable composition by exposing it to the beam of light such that multiphoton absorption of a portion of the light by the Type I photoinitiator initiates free-radical polymerization of the free-radically polymerizable compound, and such that incrementally increasing exposure to the beam of light causes less curing of at least a portion of the photocurable composition exposed to the beam of light.

In some embodiments, the free-radically polymerizable compound comprises at least one of a free-radically polymerizable acrylate or a free-radically polymerizable methacrylate.

In some embodiments, the Type I photoinitiator is selected from the group consisting of substituted or unsubstituted: benzoin ethers, benzyl ketals, α,α-dialkoxyacetophenones, α-hydroxyalkylphenones, α-dialkylaminoalkylphenones, acylphosphine oxides, acylphosphines, substituted derivatives thereof, and combinations thereof. In some embodiments, the Type I photoinitiator comprises 2-benzyl-2-(dimethylamino)-4′-morpholinobutyrophenone.

In the foregoing methods, the photocurable composition may form a layer disposed on a substrate. In addition or alternatively, the photocurable composition may further comprise an organic polymer and be substantially nonflowable.

In the foregoing methods, step c) may be repeated a plurality of times. During each repetition the beam of light is focused at a different location within the photocurable composition according to a predetermined pattern, which may include predetermined pattern variations in each of three dimensions. However, repetition of step c) is not necessary to achieve the essential benefits of the present disclosure.

Typically, the foregoing methods may further comprise developing at least a portion of the photocurable composition that is cured to at least the threshold level for developing in step c), although this is not a requirement.

Advantageously, methods according to the present disclosure, enable submicron feature fabrication at practical laser scanning speeds.

In the present disclosure:

The term “free-radical polymerization inhibitor” refers to a compound that inhibits free-radical polymerization (e.g., of free-radically polymerizable acrylates and/or methacrylates).

The term “light” refers to electromagnetic radiation, for example, in a range of from about 300 nanometers (nm) to about 1500 nm.

The term “(meth)acryl” refers to “acryl” and/or “methacryl”.

The term “microstructure” refers to a 2-D or 3-D shape having at least one critical dimension less than about 800 microns (μm), typically less than about 500 microns, or even less than 100 microns.

The term “nonlinear” in reference to absorption of light refers to a process in which the absorption of light depends on power of the intensity of the light greater than one.

The term “multiphoton absorption” refers to nonlinear simultaneous absorption of two or more photons to reach a reactive, electronic excited state that is energetically inaccessible by the absorption of a single photon of the same energy.

The term “methacrylate compound” refers to a compound having at least one methacryloyl group.

The terms “curing” and “photocuring” refer to the process of making a soluble photocurable composition (e.g., a photoresist) insoluble by polymerization (e.g., free-radical polymerization with optional crosslinking). It is possible for polymerization to occur without curing (e.g., insolubilizing) the photocurable composition, as, for example, when the termination of polymerization occurs before the extent of polymerization is sufficient to cause insolubility.

The term “simultaneous” means two events that occur within the period of 10⁻¹⁴ seconds or less.

The features and advantages of the present disclosure will be further understood upon consideration of the detailed description as well as the appended claims.

### BRIEF DESCRIPTION OF THE DRAWINGS

FIG. 1 is a schematic representation of an exemplary system useful for practicing methods according to the present disclosure.

FIG. 2 is a schematic plot of vertical voxel size versus 1/writing speed at fixed multiphoton curing conditions for a hypothetical photocurable composition exhibiting negative contrast.

FIG. 3 is a cross-sectional view of a laser beam in a Gauss-Laguerre mode TEM₀₁*.

FIG. 4 is a cross-sectional view of a laser beam in a Gauss-Laguerre mode TEM₁₀.

FIG. 5 is a schematic depiction of two dimensional 15-line pattern, written by a laser under two-photon exposure conditions, used to determine threshold writing speed and voxel height in the z-direction in the Examples. The z-axis location of the lines in the middle of the range is set at the wafer-photoresist interface.

FIG. 6 is a graph showing contrast curves for Examples 1 and 2.

FIG. 7 is a graph showing contrast curves for Examples 3 and 4.

FIG. 8 is a graph showing contrast curves for Example 3 and Comparative Example A.

FIG. 9 is a graph showing contrast curves for Examples 5-7 and Comparative Example A.

FIG. 10 is a graph showing contrast curves for Examples 8 and Comparative Example A.

FIG. 11 is a graph showing contrast curves for Examples 2 and 9.

FIGS. 12A and 12B are scanning electron microscopy (SEM) micrographs showing 3-D features generated according to Example 10.

FIG. 13 is a graph showing a contrast curve for Example 11

While the above-identified drawing figures set forth several embodiments of the present disclosure, other embodiments are also contemplated; for example, as noted in the discussion. In all cases, the disclosure is presented by way of representation and not limitation. It should be understood that numerous other modifications and embodiments can be devised by those skilled in the art, which fall within the scope and spirit of the principles of the disclosure. The figures may not be drawn to scale. Like reference numbers may have been used throughout the figures to denote like parts.

### DETAILED DESCRIPTION

Photocurable compositions useful in practice of the present disclosure include a free-radically polymerizable compound, multiphoton photoinitiator system, and typically a free-radical polymerization inhibitor (e.g., an organic free-radical polymerization inhibitor, or an inorganic free-radical inhibitor such as, for example, oxygen).

Examples of free-radically polymerizable compounds that can be used in one or more embodiments of the present disclosure include mono- and poly-acrylates and/or methacrylates such as, for example, allyl acrylate, ethyl acrylate, isopropyl methacrylate, methyl acrylate, methyl methacrylate, n-hexyl acrylate, stearyl acrylate, 1,3-butylene glycol diacrylate, 1,3-propanediol diacrylate, 1,3-propanediol dimethacrylate, 1,4-butanediol diacrylate, 1,4-cyclohexanedimethanol diacrylate, 1,4-cyclohexanediol diacrylate, 1,6-hexanediol diacrylate, 1,6-hexanediol monoacrylate monomethacrylate, alkoxylated aliphatic diacrylate, alkoxylated cyclohexanedimethanol diacrylate, alkoxylated hexanediol diacrylate, alkoxylated neopentyl glycol diacrylate, bis[1-(2-acryloxy)]-p-ethoxyphenyldimethylmethane, bis[1-(3-acryloxy-2-hydroxy)]-p-propoxyphenyldimethylmethane, 1,2,4-butanetriol trimethacrylate, caprolactone modified neopentyl glycol hydroxypivalate diacrylate, copolymerizable mixtures of (meth)acrylated monomers and oligomers, diethylene glycol diacrylate, dipropylene glycol diacrylate, ethoxylated (10) bisphenol a diacrylate, ethoxylated (3) bisphenol a diacrylate, ethoxylated (30) bisphenol a diacrylate, ethoxylated (4) bisphenol a diacrylate, ethylene glycol diacrylate, glycerol diacrylate, neopentyl glycol diacrylate, glycol hydroxypivalate diacrylate, hydroxypivalaldehyde modified trimethylolpropane diacrylate, polyethylene glycol (200) diacrylate, polyethylene glycol (400) diacrylate, polyethylene glycol (600) diacrylate, propoxylated neopentyl glycol diacrylate, the bis-acrylates and bis-methacrylates of polyethylene glycols of molecular weight about 200-500 grams per mole, tricyclodecanedimethanol diacrylate, triethylene glycol diacrylate, triethylene glycol dimethacrylate, tripropylene glycol diacrylate, tetraethylene glycol diacrylate, pentaerythritol triacrylate, glycerol triacrylate, ethoxylated triacrylates (e.g., ethoxylated (3) trimethylolpropane triacrylate, ethoxylated (6) trimethylolpropane triacrylate, ethoxylated (9) trimethylolpropane triacrylate, ethoxylated (20) trimethylolpropane triacrylate), pentaerythritol triacrylate, propoxylated triacrylates (e.g., propoxylated (3) glyceryl triacrylate, propoxylated (5.5) glyceryl triacrylate, propoxylated (3) trimethylolpropane triacrylate, propoxylated (6) trimethylolpropane triacrylate), pentaerythritol tetraacrylate, pentaerythritol tetramethacrylate, sorbitol hexaacrylate, trimethylolpropane triacrylate, tris(hydroxyethyl)isocyanurate trimethacrylate, unsaturated amides (e.g., methylene bis-acrylamide, methylene bis-methacrylamide, 1,6-hexamethylene bis-acrylamide, diethylenetriamine tris-acrylamide and beta-methacrylamidoethyl methacrylate), and combinations thereof; and vinyl compounds such as, for example, styrene, diallyl phthalate, divinyl succinate, divinyl adipate, and divinyl phthalate, and combinations thereof; and combinations thereof. Other useful free-radically polymerizable compounds include (meth)acrylated oligomers and polymers.

Suitable (meth)acrylated polymers include polymers with pendant acrylate and/or methacrylate groups, for example, having from 1 to about 50 (meth)acrylate groups per polymer chain. Examples of such polymers include aromatic acid (meth)acrylate half ester resins such as those available under the trade designation “SARBOX” (e.g., as SARBOX 400, 401, 402, 404, and 405) from Sartomer Co., Exton, Pa. Other useful reactive polymers curable by free-radical chemistry include those polymers that have a hydrocarbyl backbone and pendant peptide groups with free-radically polymerizable functionality attached thereto, such as those described in U.S. Pat. No. 5,235,015 (Ali et al.). Mixtures of two or more monomers, oligomers, and/or reactive polymers can be used if desired. Exemplary ethylenically-unsaturated species include acrylates, aromatic acid (meth)acrylate half ester resins, and polymers that have a hydrocarbyl backbone and pendant peptide groups with free-radically polymerizable functionality attached thereto.

The multiphoton photoinitiator system simultaneously absorbs at least two photons of light from the light source and generates free-radicals capable of initiating free-radical polymerization of the free-radical polymerizable compound(s) in the photocurable composition. The multiphoton photoinitiator system, enables polymerization to be confined or limited to the focal region of a focused beam of light. Such a system may comprise a one-component system, or a two- or three-component system that comprises at least one multiphoton photosensitizer, at least one photoinitiator (or electron acceptor), and, optionally, at least one electron donor. Such multi-component systems can provide enhanced sensitivity, enabling photoreaction to be effected in a shorter period of time and thereby reducing the likelihood of problems due to movement of the sample and/or one or more components of the exposure system. Advantageously, the multiphoton photoinitiator system may comprise a photochemically effective amount of at least one multiphoton absorbing compound that is capable of simultaneously absorbing at least two photons and that, optionally, has a two-photon absorption cross-section greater than that of fluorescein.

In some embodiments, the multiphoton photoinitiator system can be a one-component system that comprises a Type I photoinitiator for free-radical polymerization. Type I photoinitiators are defined to essentially undergo a unimolecular bond cleavage reaction upon absorption of light thereby yielding free radicals. Suitable Type I photoinitiators include, for example, benzoin ethers (e.g., benzoin methyl ether, benzoin ethyl ether, benzoin n-butyl ether), benzil ketals (e.g., 2,2-dimethoxy-1,2-diphenylethan-1-one available as IRGACURE 651 from Ciba Specialty Chemicals, Tarrytown, N.Y.); alpha-substituted acetophenone derivatives (e.g., 2-hydroxy-2-methyl-1-phenyl-1-propanone, which available as DAROCUR 1173 from Ciba Specialty Chemicals); and 1-hydroxycyclohexyl phenyl ketone, which is available as IRGACURE 184, from Ciba Specialty Chemicals); 2-methyl-1-(4-methylthiophenyl)-2-morpholinopropan-1-one which is available as IRGACURE 907 from Ciba Specialty Chemicals Corporation; 2-benzyl-2-(dimethylamino)-1-[4-(4-morpholinyl)phenyl]-1-butanone which is available as IRGACURE 369 from Ciba Specialty Chemicals Corporation; and acylphosphine oxides (e.g., bis(2,4,6-trimethylbenzoyl)phenylphosphine oxide, which is available as IRGACURE 819 from Ciba Specialty Chemicals, as well as 2,4,6 trimethylbenzoylethoxyphenylphosphine oxide marketed as LUCIRIN TPO-L by BASF Corp., Florham Park, N.J.), and mono- and bis-acylphosphines such as those available from Ciba Specialty Chemicals as IRGACURE 1700, IRGACURE 1800, IRGACURE 1850, IRGACURE 819 IRGACURE 2005, IRGACURE 2010, IRGACURE 2020 and DAROCUR 4265; and oligomeric photoinitiators such as, for example, ESACURE KIP 100 from Lamberti SpA, Gallarate, Italy), or as IRGACURE 651 from Ciba-Geigy, Lautertal, Germany. Combinations of two or more photoinitiators may be used. Further, sensitizers such as 2-isopropylthioxanthone may be used in conjunction with photoinitiator(s) such as “IRGACURE 369”.

In some embodiments, the multiphoton photoinitiator system can be a two-component system (e.g., a combination of an electron donor and photoinitiator) or three-component system (e.g., a combination of an electron donor, sensitizer, and photoinitiator). Multiphoton photosensitizers, electron donors, and photoinitiators (or electron acceptors) useful in two- and three-component multiphoton photoinitiator systems are described below.

Multiphoton photosensitizers are known in the art and illustrative examples having relatively large multiphoton absorption cross-sections have generally been described, for example, in U.S. Pat. No. 6,267,913 (Marder et al.). The two-photon absorption cross-section of the photosensitizer may be greater than about 1.5 times that of fluorescein, greater than about twice that of fluorescein, greater than about three times that of fluorescein, or even greater than about four times that of fluorescein. In some embodiments, the photosensitizer is soluble in the free-radically polymerizable compounds (e.g., if the free-radically polymerizable compounds is liquid) or is compatible with the free-radically polymerizable compounds and with any binders (e.g., as described below) that are included in the composition. A photosensitizer can also be selected based in part upon shelf stability considerations. Accordingly, selection of a particular photosensitizer can depend to some extent upon the particular free-radically polymerizable compounds utilized (as well as upon the choices of electron donor compound and/or photoinitiator).

Particularly useful multiphoton photosensitizers include those exhibiting large multiphoton absorption cross-sections, such as Rhodamine B (that is, N-[9-(2-carboxyphenyl)-6-(diethylamino)-3H-xanthen-3-ylidene]-N-ethylethanaminium chloride or hexafluoroantimonate) and the four classes of photosensitizers described, for example, by Marder and Perry et al. in International Patent Publication Nos. WO 98/121521 and WO 99/53242. The four classes can be described as follows: (a) molecules in which two donors are connected to a conjugated π-electron bridge; (b) molecules in which two donors are connected to a conjugated π-electron bridge which is substituted with one or more electron accepting groups; (c) molecules in which two acceptors are connected to a conjugated π-electron bridge; and (d) molecules in which two acceptors are connected to a conjugated π-electron bridge which is substituted with one or more electron donating groups (where “bridge” means a molecular fragment that connects two or more chemical groups, “donor” means an atom or group of atoms with a low ionization potential that can be bonded to a conjugated π-electron bridge, and “acceptor” means an atom or group of atoms with a high electron affinity that can be bonded to a conjugated π-electron bridge). Other useful photosensitizers are described in U.S. Pat. Nos. 6,100,405; 5,859,251; and 5,770,737 all to Reinhardt et al. as having large multiphoton absorption cross-sections, although these cross-sections were determined by a method other than that described above.

Electron donor compounds useful in the multiphoton photoinitiator system of the photocurable compositions are those compounds (other than the photosensitizer itself) that are capable of donating an electron to an electronic excited state of the photosensitizer. Such compounds may be used, optionally, to increase the multiphoton photosensitivity of the photoinitiator system, thereby reducing the exposure required to effect photoreaction of the photocurable composition. The electron donor compounds may have an oxidation potential that is greater than zero and less than or equal to that of p-dimethoxybenzene. In some embodiments, the oxidation potential is between about 0.3 and 1 volt vs. a standard saturated calomel electrode (“S.C.E.”).

Electron donor compounds are typically soluble in the photocurable composition, although this is not a requirement, and may be selected based in part upon shelf stability considerations (as described above). Suitable electron donors are generally capable of increasing the speed of cure or the image density of a photocurable composition upon exposure to light of the desired wavelength.

In general, electron donor compounds suitable for use with particular photosensitizers and photoinitiators can be selected by comparing the oxidation and reduction potentials of the three components (e.g., as described in U.S. Pat. No. 4,859,572 (Farid et al.)).

Suitable electron donor compounds include, for example, amines (including triethanolamine, hydrazine, 1,4-diazabicyclo[2.2.2]octane, triphenylamine (and its triphenylphosphine and triphenylarsine analogs), aminoaldehydes, aminosilanes, amides (including phosphoramides), ethers (including thioethers), ureas (including thioureas), sulfinic acids and their salts, salts of ferrocyanide, ascorbic acid and its salts, dithiocarbamic acid and its salts, salts of xanthates, salts of ethylenediaminetetraacetic acid, salts of (alkyl)ₙ(aryl)ₘborates (wherein n+m=4) (e.g., tetraalkylammonium salts), various organometallic compounds such as SnR₄ compounds (where each R is independently chosen from among alkyl, aralkyl (particularly, benzyl), aryl, and alkaryl groups) (e.g., such compounds as n-C₃H₇Sn(CH₃)₃, (allyl)Sn(CH₃)₃, and (benzyl)Sn(n-C₃H₇)₃), ferrocene, and mixtures thereof. The electron donor compound can be unsubstituted or can be substituted with one or more non-interfering substituents. In some embodiments, suitable electron donor compounds contain an electron donor atom (such as a nitrogen, oxygen, phosphorus, or sulfur atom) and an abstractable hydrogen atom bonded to a carbon or silicon atom alpha to the electron donor atom.

Suitable photoinitiators (that is, electron acceptor compounds) for use in the photocurable compositions are those that are capable of being photosensitized by accepting an electron from an electronic excited state of the multiphoton photosensitizer, resulting in the formation of at least one free radical and/or acid. Such photoinitiators include iodonium salts (e.g., diaryliodonium salts), sulfonium salts (e.g., triarylsulfonium salts optionally substituted with alkyl or alkoxy groups, and optionally having 2,2′-oxy groups bridging adjacent aryl moieties), and combinations thereof. Suitable iodonium salts include those described in U.S. Pat. No. 5,545,676 (Palazzotto et al.). The iodonium salt can be for example a simple salt (e.g., containing an anion such as chloride, bromide, iodide, or benzenesulfonate) or a metal complex salt (e.g., containing SbF₆—, PF₆—, BF₄—, tetrakis(perfluorophenyl)borate, SbF₅OH— or AsF₆—). Mixtures of iodonium salts can be used if desired.

The multiphoton photoinitiator system is typically selected to be soluble in the photocurable composition and shelf-stable (that is, does not spontaneously promote reaction of the photocurable composition), although these are not requirements. Accordingly, selection of a particular multiphoton photoinitiator system can depend to some extent upon the particular photocurable composition.

The components of the multiphoton photoinitiator system, after removal of any volatile components such as solvent, are present in photochemically effective amounts. Generally, the photocurable composition contains at least about 5 percent (e.g., at least about 10 percent or at least about 20 percent) up to about 99.79 percent (e.g., up to about 95 percent or up to about 80 percent) by weight of one or more free-radically polymerizable compounds; at least about 0.01 percent (e.g., at least about 0.1 percent or at least about 0.2 percent) up to about 10 percent (e.g., up to about 5 percent or up to about 2 percent) by weight of the multiphoton initiator system, although other amounts may also be used. For example in the case of two and three-components multiphoton photoinitiator systems, up to about 10 percent by weight (e.g., up to about 5 percent by weight) by weight of one or more electron donor compounds (e.g., at least about 0.1 percent by weight or from about 0.1 to about 5 percent by weight); up to about 10 percent by weight (e.g., up to about 5 percent by weight) of photosensitizer (e.g., at least about 0.001 percent by weight to one percent by weight); and from about 0.1 percent by weight to about 10 percent by weight of one or more electron acceptor compounds (e.g., from about 0.1 percent by weight to about 5 percent by weight) based upon the total weight of solids in the photocurable composition, although other amounts may also be used. In embodiments wherein an organic free-radical inhibitor is present, it may be present in an effective amount. In some embodiments, organic free-radical inhibitor is present in an amount of from about 0.01 to about 2 percent by weight, from about 0.01 to about 0.75 percent by weight, or from about 0.1 to about 0.5 percent by weight of the photocurable composition, although other amounts may also be used.

Further details concerning two- and three-component photoinitiator systems can be found in U.S. Pat. No. 8,004,767 B2 (DeVoe et al.).

The photocurable composition may also include optional components such as, for example, one or more polymeric binders, stabilizers, fragrances, fillers, thixotropic agents, colorants, thermal free-radical initiators, monohydroxy and polyhydroxy compounds, plasticizers, toughening agents, fillers, abrasive granules, stabilizers, light stabilizers, antioxidants, flow agents, bodying agents, flatting agents, colorants, blowing agents, fungicides, bactericides, surfactants, fillers (e.g., glass and ceramic beads, and reinforcing materials such as woven and non-woven webs of organic and inorganic fibers.

In some embodiments, the photocurable composition includes a polymeric binder, for example, to control viscosity and to provide film-forming properties. Such polymeric binders can generally be chosen to be compatible with the free-radically polymerizable compounds. For example, polymeric binders that are soluble in the same solvent that is used for the free-radically polymerizable compounds, and that are free of functional groups that can adversely affect the course of reaction of the free-radically polymerizable compounds, can be utilized. Binders can be of a molecular weight suitable to achieve desired film-forming properties and solution rheology (e.g., molecular weights between about 5,000 and 1,000,000 Daltons, between about 10,000 and 500,000 Daltons, or between about 15,000 and 250,000 Daltons). Suitable polymeric binders include, for example, polystyrene, poly(methyl methacrylate), poly(styrene)-co-(acrylonitrile), and cellulose acetate butyrate.

In some embodiments, the photocurable composition may comprise about 30 percent by weight of poly(methyl methacrylate) (120,000 grams/mole), about 35 percent by weight of ethoxylated trimethylolpropane triacrylate (available as SR-9008 from Sartomer Co., Inc., Exton, Pa.), and about 35 percent by weight of tris-(2-hydroxyethyl)isocyanurate triacrylate.

The photocurable composition may be made by combining the above components using methods well known in the art such as, for example, by mixing them together (e.g., with stirring or agitation) under appropriate “safe-light” conditions to prevent unwanted single-photon initiated photopolymerization that may cause premature curing of the photocurable composition. Components of the photocurable composition can be combined under “safe light” conditions using any order and manner of combination (optionally, with stirring or agitation), although it is sometimes advantageous (from a shelf-life and thermal stability standpoint) to add the photoinitiator last (and after any heating step that is optionally used to facilitate dissolution of other components). Solvent can be used, if desired, provided that the solvent is chosen so as to not react appreciably with the components of the composition. Suitable solvents include, for example, acetone, dichloromethane, cyclopentanone, and acetonitrile. The free-radically polymerizable compounds may also sometimes serve as a solvent for the other components.

The photocurable composition may be present in any form such as, for example, a liquid or a solid. Prior to exposure to the light beam, the photocurable compositions can be coated on a substrate, if desired, by any of a variety of coating methods known to those skilled in the art (including, for example, knife coating and spin coating). The substrate can be chosen from a wide variety of films, sheets, and other surfaces (including silicon wafers and glass plates), depending upon the particular application and the method of exposure to be utilized. Prior to coating the substrate with the multiphoton curable photocurable composition, the substrate may be primed with a suitable compound, such as a compound that includes a silane group and a functional group similar to the photocurable composition. Suitable primers include, for example, 3-trimethoxysilylpropyl methacrylate. Useful substrates may advantageously be sufficiently flat to enable the preparation of a layer of photocurable composition having a uniform thickness. For applications where coating is less desirable, the photocurable compositions can be exposed in bulk form.

Multiphoton photocuring as practiced herein involves free-radical polymerization of free-radically polymerizable components in the photocurable composition that proceeds to such an extent that insolubilization of a volume region of the photocurable composition occurs (e.g., resulting in one or more voxels). Typically, this occurs by formation of a crosslinked polymer network which results if multifunctional free-radically polymerizable monomers are included in the photocurable composition, although other factors may also be influential. It will be noted that insolubilization will typically depend on the degree of polymerization/crosslinking, and thus the photocurable composition may not be insolubilized (e.g., cured) even though some polymerization has occurred. Further insolubilization may also depend on the specific choice of developing conditions (e.g., the rinse solvent and/or temperature).

Generally speaking, two conditions must be met in order for multiphoton photocuring by exposure to light to occur. The first condition is that the light (e.g., high intensity laser light) must have sufficient intensity such that multiphoton absorption can occur. Additional benefit may be achieved if the light is coherent, e.g., as in the case of laser light. At a first approximation, the probability of nonlinear multiphoton absorption increases exponentially with the number of photons absorbed. Thus, for practical reasons multiphoton absorption is typically practiced as two-photon absorption, especially in condensed phase materials (e.g., solids or liquids).

In multiphoton photocuring processes, multiphoton absorption of the light by a multiphoton initiating system causes it to react or decompose thereby forming initiating species (e.g., free-radicals) that cause curing (e.g., by free-radical by polymerization) of a region of the photocurable composition. Accordingly, the second condition is that a sufficient number of initiating species must be generated to cause sufficient curing of the photocurable composition that solvent developing will not remove desired material. This latter condition relates to the dosage of light received (e.g., as reflected by writing speed of the beam of light).

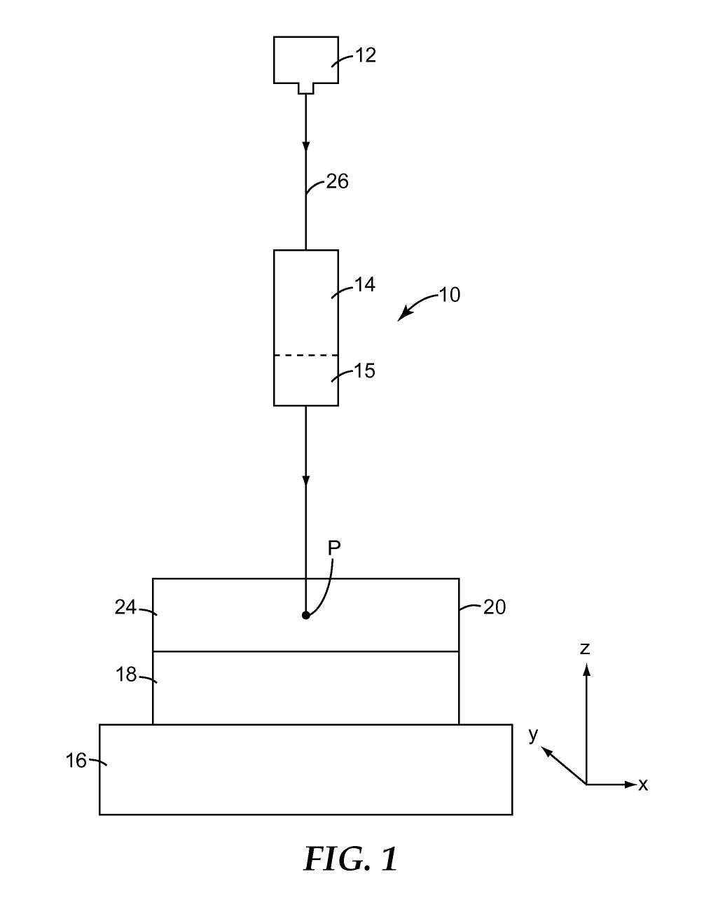

One exemplary type of system that can be used is shown in FIG. 1. Referring to FIG. 1, fabrication system 10 includes light source 12, optical system 14 comprising a final optical element 15 (optionally including galvo-mirrors and a telescope to control beam divergence), and moveable stage 16. Stage 16 is moveable in one, two, or, more typically, three dimensions. Light beam 26 originating from light source 12 passes through optical system 14 and leaves through final optical element 15 which focuses it to a point P within layer 20, thereby controlling the three-dimensional spatial distribution of light intensity within the composition, and causing at least a portion of photocurable composition 24 in the vicinity of point P to become more, or less, soluble in at least one solvent than it was immediately prior to exposure to light beam 26. By moving stage 16, or by directing light beam 26 (e.g., moving a laser beam using galvo-mirrors) in combination with moving one or more elements of optical system 14, the focal point P can be scanned or translated in a three-dimensional pattern that corresponds to a desired shape. For example, stage 16 can be moved in x and y dimensions and final optical element 15 moved in the z dimension to control the position of point P. The reacted or partially reacted portion of the photocurable composition 24 then creates a three-dimensional structure of a desired shape.

Substrate 18 mounted on stage 16 has a layer 20 comprising multiphoton photoreactive composition 24 disposed thereon. Light beam 26 originating from light source 12 passes through optical system 14 and leaves through final optical element 15 which focuses it to a point P within layer 20, thereby controlling the three-dimensional spatial distribution of light intensity within multiphoton photoreactive composition 24. and causing at least a portion of multiphoton photoreactive composition 24 in the vicinity of point P to cure.

By moving stage 16, or by directing light beam 26 (e.g., moving a laser beam using galvo-mirrors and a telescope) in combination with moving one or more elements of optical system 14, the focal point P can be scanned or translated in a three-dimensional pattern that corresponds to a desired shape. The resulting cured or partially cured portion of multiphoton photoreactive composition 24 then creates a three-dimensional structure of the desired shape. If it is desired to have the three-dimensional structure anchored to the substrate after development, the focal point P should be anchored at the interface of the layer 20 and the substrate 18 for those voxels at the bottom of the structure. For example, in a single pass the surface profile (corresponding to a thickness of about one volume pixel or voxel) of one or more light extraction structures can be exposed or imaged, which upon development can form the surface of the structure(s).

The exposure or imaging of a surface profile can be carried out by scanning at least the perimeter of a planar slice of a desired three-dimensional structure, and then scanning a plurality of, typically parallel, planar slices to complete the structure. Slice thickness can be controlled, together with proper energy dose applied, to achieve a sufficiently low level of surface roughness to provide quality structures. For example, smaller slice thicknesses can be desirable in regions of greater structure taper to aid in achieving high structure fidelity, but larger slice thicknesses can be utilized in regions of less structure taper to aid in maintaining useful fabrication times. In this way, a surface roughness less than the slice thickness (e.g., less than about one-half of the slice thickness, or even less than about one-quarter of the slice thickness) can be achieved without sacrificing fabrication speed (i.e., throughput or number of structures fabricated per unit time).

When the multiphoton photoreactive composition 24 is coated on a substrate that exhibits a degree of non-planarity that is of the same or greater size magnitude as voxel height, it can be desirable to compensate for the non-planarity to avoid optically- or physically-defective structures. This can be accomplished by locating (e.g., using a confocal interface locator system) the position of the interface between the substrate and the portion of the multiphoton photoreactive composition 24 that is to be exposed, and then adjusting the location of the optical system 14 appropriately to focus light beam 26 at the interface. An exemplary such procedure is described in detail in U.S. Pat. No. 7,893,410 B2 (Sykora et al.). This procedure can be followed for at least one structure out of every twenty structures in an array (e.g., at least one out of every ten structures, or for each structure in the array).

Light source 12 can be any light source (e.g., a laser) that provides sufficient intensity to effect multiphoton absorption at a wavelength appropriate for the multiphoton photoinitiator system included in the photocurable composition. Such wavelengths can be in the range of, for example, from about 300 to about 1500 nanometers (nm), from about 400 to about 1100 nm, from about 600 to about 900 nm, or from about 750 to about 850 nm, inclusive. Typically, the light fluence (e.g., peak intensity of a pulsed laser) is greater than about 10⁶ W/cm². The upper limit on the light fluence is generally dictated by the ablation threshold of the photocurable composition. Exemplary suitable sources of light include high power lamps and lasers. In general, the light should be of a wavelength that is not absorbed directly (i.e., by one-photon absorption) by the photocurable composition, but is of an appropriate wavelength (λ) such that multiphoton (e.g., two-photon) absorption corresponds to a major absorption by the multiphoton photoinitiator system at half its wavelength (λ/2). Such wavelengths can generally be in the range of about 300 to about 1500 nm (e.g., from about 400 to about 1100 nm, from about 600 to about 900 nm, or from about 750 to about 850 nm, all ranges inclusive). Typically, the light fluence (e.g., peak intensity of a pulsed laser) is greater than about 10⁶ watts per square centimeter (W/cm²). The upper limit on the light fluence is generally dictated by the ablation threshold of the photocurable composition.

Suitable light sources include, for example, ultrafast lasers such as picosecond and femtosecond lasers. For example, suitable femtosecond lasers include near-infrared titanium sapphire oscillators (e.g., those available from Coherent, Santa Clara, Calif., under the trade designation “MIRA OPTIMA 900-F”) pumped by an argon ion laser (e.g., those available from Coherent under the trade designation “INNOVA”). This laser, operating at 76 MHz, has a pulse width of less than 200 femtoseconds, is tunable between 700 and 980 nm, and has average power up to 1.4 Watts. Another useful laser is available from Spectra-Physics, Mountain View, Calif., under the trade designation “MAI TAI”, tunable to wavelengths in a range of from 750 to 850 nanometers, and having a repetition frequency of 80 megahertz, and a pulse width of about 100 femtoseconds (10⁻¹³ sec), with an average power level of up to one Watt.

Additional suitable lasers include, Q-switched Nd:YAG lasers (e.g., those available from Spectra-Physics under the trade designation “QUANTA-RAY PRO”), visible wavelength dye lasers (e.g., those available from Spectra-Physics under the trade designation “SIRAH” pumped by a QUANTA-RAY PRO Q-switched Nd:YAG laser, and Q-switched diode pumped lasers (e.g., those available from Spectra-Physics under the trade designation “FCBAR”) can also be utilized.

Additional light sources include near infrared pulsed lasers having a pulse length less than about 10⁻⁸ second (e.g., less than about 10⁻⁹ second, or even less than about 10⁻¹¹ second). Other pulse lengths can be used as long as the peak intensity and ablation threshold criteria above are met. Pulsed light can, for example, have a pulse frequency of from about one kilohertz up to about 50 megahertz (MHz), or even more. Continuous wave lasers can also be used.

Optical system 14 can include, for example, refractive optical elements (e.g., lenses or microlens arrays), reflective optical elements (e.g., retroreflectors or focusing mirrors), diffractive optical elements (e.g., gratings, phase masks, and holograms), polarizing optical elements (e.g., linear polarizers, circular polarizers, and waveplates), dispersive optical elements (e.g., prisms and gratings), diffusers, Pockels cells, waveguides, and the like. Such optical elements are useful for focusing, beam delivery, beam/mode shaping, pulse shaping, and pulse timing. Generally, combinations of optical elements can be utilized, and other appropriate combinations will be recognized by those skilled in the art.

Final optical element 15 may include, for example, one or more refractive, reflective, and/or diffractive optical elements. In one embodiment, an objective such as, for example, those used in microscopy may be conveniently obtained from commercial sources such as, for example, Carl Zeiss, North America, Thornwood, N.Y., and used as final optical element 15. For example, fabrication system 10 can include a scanning confocal microscope (e.g., those available from Bio-Rad Laboratories, Hercules, Calif., under the trade designation “MRC600”) equipped with a 0.75 NA objective (such as, e.g., those available from Carl Zeiss, North America under the trade designation “20× FLUAR”). The numeric aperture of final optical element 15 may have any value in the range of from 0.65 to 1.46, inclusive. Useful air objectives typically have a numeric aperture in a range of from 0.65 to about 0.95. Useful liquid objectives (e.g., oil immersion objectives) typically have a numeric aperture in a range of from greater than about 1.0 up to 1.46.

It may often be desirable to use optics with relatively large numerical aperture to provide highly-focused light. However, any combination of optical elements that provides a desired intensity profile (and spatial placement thereof) can be utilized.

Exposure times generally depend upon the type of exposure system used to cause reaction of the free-radically polymerizable compounds in the photocurable composition (and its accompanying variables such as numerical aperture, geometry of light intensity spatial distribution, the peak light intensity during the laser pulse (higher intensity and shorter pulse duration roughly correspond to peak light intensity)), as well as upon the nature of the photocurable composition. Generally, higher peak light intensity in the regions of focus allows shorter exposure times, everything else being equal. Linear imaging or “writing” speeds generally can be about 0.5 to 100,000 microns/second using a laser pulse duration of about 10⁻⁸ to 10⁻¹⁵ second (e.g., about 10⁻¹¹ to 10⁻¹⁴ second) and about 10² to 10⁹ pulses per second (e.g., about 10³ to 10⁸ pulses per second).

Unless otherwise specified, multiple light beams, which may be different in cross-sectional beam intensity profile and/or temporal profile may be used. The light beams may originate from one or more light sources (e.g., lasers). Using same light source for multiple beams, simplifies the multiphoton photocuring process may simplify the system design and implementation in some cases.

Through multiphoton absorption, exposure to light beam 26 induces a reaction in the photocurable composition that produces one or more volume regions of cured material containing free-radically polymerized material. The resulting pattern of cured and uncured material can then be realized by a conventional development process, for example, by removing uncured regions. Optionally, after exposure of only the surface profile of a desired structure, typically followed by solvent development, a non-imagewise exposure using actinic radiation (e.g., light that causes curing through a one-photon absorption process) can be carried out to effect additional curing of any residual uncured photocurable composition. Complex three-dimensional structures and structure arrays can be prepared in this manner.

In order to successfully solvent develop the exposed photocurable composition and obtain a fabricated structure, a threshold dose of light (i.e., threshold dose) is typically required in volume regions (voxels) of the photocurable composition where curing is desired. Accordingly, the dosage of light is typically selected such that volume regions where curing is desired receive at least the threshold level (e.g., up to ten times the threshold level), and in volume regions where negative contrast is to be exploited, the dosage (and typically intensity) will be greater. The threshold dose is typically process specific, and may depend on variables such as, for example, the wavelength, pulse frequency, intensity of the light, the specific photocurable composition, the specific structure being fabricated, or the process used for solvent development. Thus, each set of process parameters is typically associated with a specific threshold dose.

Through multiphoton absorption, light beam 26 induces a free-radical polymerization reaction in the photocurable composition that produces a volume region of material having solubility characteristics different from unexposed regions of the photocurable composition. The resulting pattern of differential solubility can then be realized by a conventional development process, for example, by removing either exposed or unexposed regions. The exposed photocurable composition can be developed, for example, by placing the exposed photocurable composition into solvent to dissolve regions of higher solvent solubility, rinsing with solvent, evaporation, oxygen plasma etching, or by other known methods, and combinations thereof. Non-limiting solvents that may be used for developing the exposed photocurable composition include aqueous solvents such as, for example, water (e.g., having a pH in a range of from 1 to 12) and miscible blends of water with organic solvents (e.g., methanol, ethanol, propanol, acetone, acetonitrile, dimethylformamide, N-methylpyrrolidone, mixtures thereof, and the like); and organic solvents. Exemplary useful organic solvents include alcohols (e.g., methanol, ethanol, propanol), ketones (e.g., acetone, cyclopentanone, methyl ethyl ketone), aromatics (e.g., toluene), halocarbons (e.g., methylene chloride, chloroform), nitriles (e.g., acetonitrile), esters (e.g., ethyl acetate, propylene glycol methyl ether acetate), ethers (e.g., diethyl ether, tetrahydrofuran), amides (e.g., N-methylpyrrolidone), can combinations thereof.

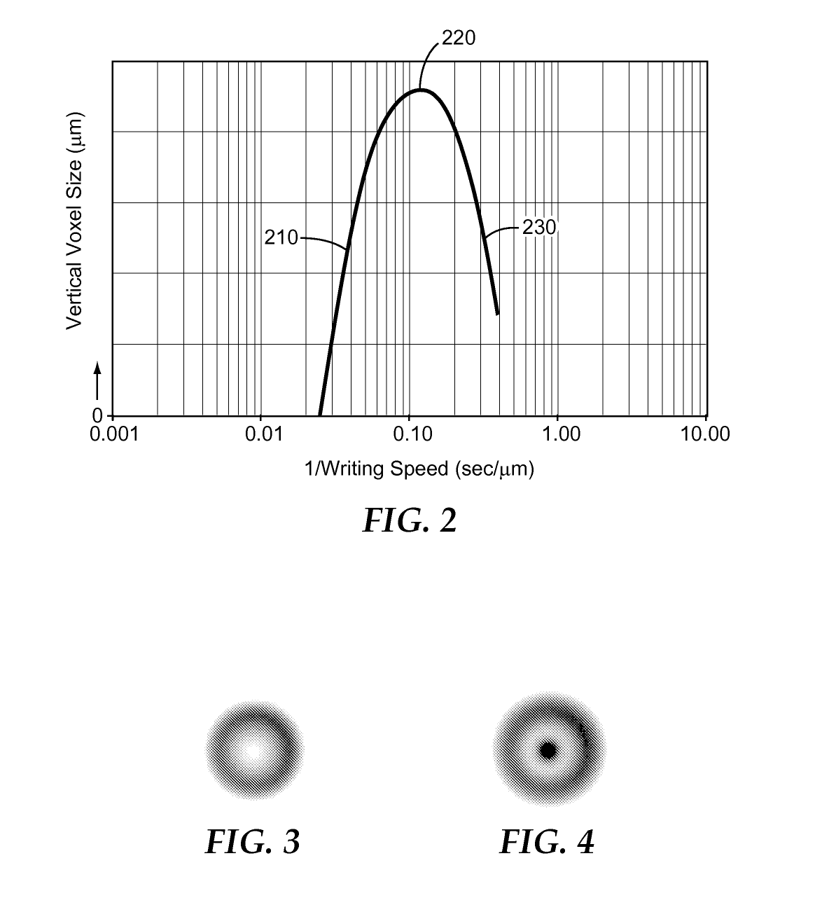

Suitable photocurable compositions for practicing the present disclosure exhibit negative contrast under certain process conditions. For example, if exposure is carried out above the threshold dose necessary to obtain multiphoton absorption, the photocurable composition may exhibit increasing cure then decreasing cure with increasing dose of the light. This can be seen by plotting the vertical voxel size (e.g., as obtained after solvent developing) versus 1/writing speed for fixed multiphoton curing conditions, for example, as shown in FIG. 2, wherein writing speed reflects the translational speed of a laser beam across a body including a photocurable composition. In FIG. 2, increasing vertical voxel size with decreasing writing speed (i.e., increasing 1/Writing Speed corresponding to increasing dose) is shown in region 210, and is typical of many multiphoton processes. However, with further decrease in the writing speed (i.e., further increase in 1/Writing Speed) a maximum level 220 is achieved. Decreasing the writing speed into region 230 increases the dose still further, and results in decreasing vertical voxel size. This reduced curing with increased dosage is an example of negative contrast (i.e., contrast curve with a region of negative slope). This negative contrast behavior can be utilized advantageously according to the present disclosure to provide imaging capability below the diffraction limit normally associated with imaging using light.

In order to use negative contrast behavior to fabricate structures formed from voxels having dimensions below the diffraction limit for the light used, there needs to be an uneven spatial profile of light impinging on the photocurable composition. For example, a light beam formed by combining two separate light beams may have higher intensity and/or dose in some portions than in others, for example, as described herein. Under conditions where negative contrast is observed photocuring will be inhibited in regions of maximum intensity/dosage, while adjacent regions will exhibit a greater degree of photocuring.

Without wishing to be bound by theory, the present inventors believe they have discovered that negative contrast is a result of excess production of free-radicals resulting in premature termination of free-radical polymerization and a reduced extent of cure.

Accordingly, a single tightly focused light beam having an uneven beam intensity profile can be used to fabricate structures and elements with submicron resolution (e.g., as described hereinabove). In one embodiment, the light beam has a cross-section in which intensity is highest in a peripheral outer region and very low in the center of the beam. For example, the beam of light may have a cross-sectional beam profile comprising an inner region having a relatively lower intensity of the light bounded by an outer region having a relatively higher intensity of the light, and wherein the inner region and the outer region have the same temporal profile (which may be continuous or pulsed). This may be achieved for example, using a light beam in a Gauss-Laguerre mode (e.g., TEM₀₁* (donut shape, shown in FIG. 3) or TEM₁₀ (“bullseye” shape, shown in FIG. 4)), or Gauss-Hermite mode, which can be formed with an appropriate phase mask according to known methods. If using a light beam in a TEM₀₁* Gauss-Laguerre mode, light in the outer region focused on the photocurable composition is of sufficient intensity and dosage that the curing of the photocurable composition is inhibited, relative to curing that occurs due to light in the inner region (it will be recognized that there will generally always be at least some light in the inner region). As a result, curing preferentially occurs in the inner region, and decreases as it approaches the outer region, resulting in cured volumes (voxels) smaller than would be obtainable by conventional single light beam methods. In some embodiments, this may result in a single feature formed at the center of the beam cross-section, while in other embodiments this may result in a bullseye-shaped structure comprising a central dot surrounded by an outer ring spaced apart from the dot. Using a beam of light in a TEM₁₀ Gauss-Laguerre mode can similarly result in formation of submicron structures such as rings and tubes. Advantageously, this method simplifies the optical steering requirements that may be present in the case of multiple bright beams, and allows formation of very small micron-sized or submicron-sized structures at slower writing speeds than other conventional multiphoton methods, which may result in increased process control.

While the preceding section describes use of laser beams comprising an inner region having a relatively lower intensity of the light bounded by an outer region having a relatively higher intensity of the light, in some methods of the present disclosure, it may be advantageous to use other laser beam modes, for example, if writing lines. Examples of laser modes that may be used accordingly include TEM₀₁, TEM₀₂, TEM₀₃, and TEM₁₁.

In another application of the discovery of the believed cause of negative contrast, the present disclosure also achieves negative contrast during multiphoton photocuring of photoreactive systems that are substantially free of oxygen. Advantages and methods of using negative contrast photocurable compositions for fabrication of fine structures is described hereinabove.

Oxygen is well-known to inhibit free-radical polymerization either alone or optionally in conjunction with certain inhibitors that only are effective in the presence of molecular oxygen (e.g., such as, for example, hydroquinone monomethyl ether (MEHQ)). In this embodiment, a free-radical polymerization inhibitor other than oxygen is included in the photocurable composition and provides the benefit otherwise provided by oxygen. Remarkably, in this embodiment, negative contrast imaging can be achieved using levels of organic free-radical polymerization inhibitors that are well in excess of normal levels that would be included in free-radically polymerizable compositions. For example, in this embodiment, the level of organic free-radical polymerization inhibitor may be included in the photocurable composition in an amount in the range of from 0.01 to 2 percent (e.g., from about 0.1 to about 0.75 percent by weight), based on the total weight of the photocurable composition, although other amounts can also be used.

Advantageously, in this embodiment substantial lack of molecular oxygen makes it possible to tune the sensitivity of the photocurable composition by adjusting the level of organic free-radical polymerization inhibitor. Since certain organic free-radical polymerization inhibitors such as, for example, phenol type antioxidants (e.g., hydroquinone, 4-methoxyphenol (MEHQ), and 2,6-di-tert-butyl-4-methylphenol) are generally only effective to inhibit free-radical polymerization in the presence of molecular oxygen, they will typically be of little or no use in this embodiment.

Useful organic free-radical polymerization inhibitors that may inhibit free-radical polymerization in the absence of oxygen include, for example, phenothiazine and amine oxide radicals (e.g., 2,2,6,6-tetramethylpiperidinooxy (i.e., TEMPO), 4-hydroxy-TEMPO; 4-acetamido-TEMPO, 4-amino-TEMPO, 4-cyano-TEMPO, 4-(2-iodoacetamido)-TEMPO, 4-oxo-TEMPO, 4-methoxy-TEMPO, 4-phosphonooxy-TEMPO hydrate, poly(ethylene glycol)-bis-TEMPO, 4-methanesulfonyloxy-TEMPO, 4-methacryloyloxy-TEMPO, bis(1-oxyl-2,2,6,6-tetramethylpiperidin-4-yl) sebacate); 1,3,5-triphenylverdazyl radical, galvinoxyl radical; 1,3-bisdiphenylene-2-phenylallyl radical (Koelsch's radical); and N— nitrosophenylhydroxylamine salts such as, for example, those available from Wako Chemical as Q-1300 and Q-1301.

In yet another application of the present discovery of the believed cause of negative contrast, the present disclosure also achieves negative contrast behavior during multiphoton curing of photoreactive systems comprising a free-radically polymerizable compound and a Type I photoinitiator, both described hereinabove, and at least one free-radical polymerization inhibitor. In this embodiment, free-radically polymerizable methacrylates, acrylates, and similar compounds can be used.

Type I photoinitiators enjoy advantages such as ready availability from commercial sources at relatively low price relative to other known multiphoton photoinitiator systems. However, negative contrast has not been observed until now during multiphoton curing of photocurable compositions. Accordingly, it is presently discovered that negative contrast can be observed in free-radically curable systems comprising a free-radically polymerizable compound (e.g., acrylate or methacrylate). In some embodiments, the free-radically curable systems comprising methacrylates contain less than one percent by weight, or even less than 0.1 percent by weight, of other free-radically polymerizable compounds such as, for example, acrylates and acrylamides, based on the total weight of the photocurable composition. In some cases, the photocurable composition may even be free of free-radically polymerizable acrylate and acrylamide compounds. Advantages and methods of multiphoton curing of photocurable compositions under conditions of negative contrast, for example, during fabrication of fine structures is described hereinabove.

Select embodiments of the present disclosure are set forth in detail below.

### Select Embodiments of the Disclosure

In a first embodiment, the present disclosure provides a method comprising the steps:

a) providing a beam of light, wherein the beam of light has a cross-sectional beam profile comprising an inner region having a relatively lower intensity of the light bounded by an outer region having a relatively higher intensity of the light, and wherein the inner region and the outer region have the same temporal profile;

b) providing a photocurable composition, wherein the photocurable composition comprises a free-radically polymerizable compound, a free-radical polymerization inhibitor, and a multiphoton photoinitiator system;

c) exposing at least a portion of the photocurable composition to the beam of light such that multiphoton absorption of a portion of the light by the multiphoton photoinitiator system initiates free-radical polymerization of at least a portion of the free-radically polymerizable compound, wherein irradiating the photocurable composition with at least a portion of the inner region of the beam of light causes curing of a portion of the photocurable composition to at least a threshold level for developing, and wherein irradiating the photocurable composition with at least a portion of the outer region of the beam of light adjacent to the inner region does not cause curing of the photocurable composition to at least the threshold level for developing.

In a second embodiment, the present disclosure provides a method according to the first embodiment, wherein the photocurable composition further comprises an organic polymer, and wherein the photocurable composition is substantially nonflowable.

In a third embodiment, the present disclosure provides a method according to the first or second embodiment, wherein the outer region of the cross-sectional beam profile is substantially annular.

In a fourth embodiment, the present disclosure provides a method according to any one of the first to third embodiments, wherein the beam of light comprises a laser beam in a Gauss-Laguerre mode.

In a fifth embodiment, the present disclosure provides a method according to any one of the first to fourth embodiments, wherein the photocurable composition forms a layer, and wherein the layer is disposed on a substrate.

In a sixth embodiment, the present disclosure provides a method according to any one of the first to fifth embodiments, wherein step c) is repeated a plurality of times, and wherein each repetition the beam of light is focused at a different location within the photocurable composition according to a predetermined pattern.

In a seventh embodiment, the present disclosure provides a method according to the sixth embodiment, wherein the predetermined pattern includes predetermined pattern variations in each of three dimensions.

In an eighth embodiment, the present disclosure provides a method according to any one of the first to seventh embodiments, further comprising developing at least a portion of the photocurable composition that is cured to at least the threshold level for developing in step c).

In a ninth embodiment, the present disclosure provides a method according to any one of the first to eighth embodiments, wherein the free-radical polymerization inhibitor comprises a free-radical polymerization inhibitor other than molecular oxygen.

In a tenth embodiment, the present disclosure provides a method according to any one of the first to ninth embodiments, wherein the free-radically polymerizable compound comprises at least two acryloyl groups.

In an eleventh embodiment, the present disclosure provides a method comprising the steps:

a) providing at least one beam of light;

b) providing a photocurable composition, wherein the photocurable composition comprises a free-radically polymerizable compound, a free-radical polymerization inhibitor other than molecular oxygen, and a multiphoton photoinitiator system, wherein the free-radical polymerization inhibitor is effective in the absence of oxygen;

c) at least partially curing at least a portion of the photocurable composition by exposing it to the at least one beam of light such that multiphoton absorption of a portion of the light by the multiphoton photoinitiator system initiates free-radical polymerization of the free-radically polymerizable compound, and such that incrementally increasing exposure to the beam of light causes less curing of at least a portion of the photocurable composition exposed to the beam of light, wherein the photocurable composition is substantially free of molecular oxygen prior to said exposing the photocurable composition to the beam of light.

In a twelfth embodiment, the present disclosure provides a method according to the eleventh embodiment, wherein, based on a total weight of the photocurable composition, the photocurable composition comprises from about 0.1 to about 0.5 percent by weight of the free-radical polymerization inhibitor.

In a thirteenth embodiment, the present disclosure provides a method according to the eleventh or twelfth embodiment, wherein the free-radically polymerizable compound comprises at least two methacryloyl groups, and wherein the photocurable composition is substantially free of acrylates.

In a fourteenth embodiment, the present disclosure provides a method according to any one of the eleventh to thirteenth embodiments, wherein the photocurable composition further comprises an organic polymer, and is substantially nonflowable.

In a fifteenth embodiment, the present disclosure provides a method according to any one of the eleventh to fourteenth embodiments, wherein the photocurable composition forms a layer, and wherein the layer is disposed on a substrate.

In a sixteenth embodiment, the present disclosure provides a method according to any one of the eleventh to fifteenth embodiments, wherein step c) is repeated a plurality of times, and wherein each repetition the beam of light is focused at a different location within the photocurable composition according to a predetermined pattern.

In a seventeenth embodiment, the present disclosure provides a method according to any one of the eleventh to sixteenth embodiments, wherein the predetermined pattern includes predetermined pattern variations in each of three dimensions.

In an eighteenth embodiment, the present disclosure provides a method according to any one of the eleventh to seventeenth embodiments, further comprising developing at least a portion of the photocurable composition that is cured to at least the threshold level for developing in step c).

In a nineteenth embodiment, the present disclosure provides a method comprising the steps:

a) providing a beam of light;

b) providing a photocurable composition, wherein the photocurable composition comprises:
a free-radically polymerizable compound,
a Type I photoinitiator, and
a free-radical polymerization inhibitor;

c) at least partially curing at least a portion of the photocurable composition by exposing it to the beam of light such that multiphoton absorption of a portion of the light by the Type I photoinitiator initiates free-radical polymerization of the free-radically polymerizable compound, and such that incrementally increasing exposure to the beam of light causes less curing of at least a portion of the photocurable composition exposed to the beam of light.

In a twentieth embodiment, the present disclosure provides a method according to the nineteenth embodiment, further comprising developing at least a portion of the photocurable composition that is cured to at least the threshold level for developing in step c).

In a twenty-first embodiment, the present disclosure provides a method according to the nineteenth or twentieth embodiment, wherein a free-radically polymerizable compound comprises at least one of a free-radically polymerizable acrylate or a free-radically polymerizable methacrylate.

In a twenty-second embodiment, the present disclosure provides a method according to the twenty-first embodiment, wherein the free-radically polymerizable compound comprises a free-radically polymerizable methacrylate.

In a twenty-third embodiment, the present disclosure provides a method according to any one of the nineteenth to twenty-second embodiments, wherein the Type I photoinitiator is the Type I photoinitiator is selected from the group consisting of substituted or unsubstituted: benzoin ethers, benzyl ketals, α,α-dialkoxyacetophenones, α-hydroxyalkylphenones, α-dialkylaminoalkylphenones, acylphosphine oxides, acylphosphines, substituted derivatives thereof, and combinations thereof.

In a twenty-fourth embodiment, the present disclosure provides a method according to any one of the nineteenth to twenty-third embodiments, wherein the Type I photoinitiator comprises 2-benzyl-2-(dimethylamino)-4′-morpholinobutyrophenone.

In a twenty-fifth embodiment, the present disclosure provides a method according to any one of the nineteenth to twenty-fourth embodiments, wherein the photocurable composition further comprises an organic polymer, and is substantially nonflowable.

In a twenty-sixth embodiment, the present disclosure provides a method according to the twenty-fifth embodiments, wherein the photocurable composition forms a layer, and wherein the layer is disposed on a substrate.

In a twenty-seventh embodiment, the present disclosure provides a method according to the twenty-sixth embodiments, wherein step c) is repeated a plurality of times, and wherein each repetition the beam of light is focused at a different location within the photocurable composition according to a predetermined pattern.

In a twenty-eighth embodiment, the present disclosure provides a method according to the twenty-seventh embodiments, wherein the predetermined pattern includes predetermined pattern variations in each of three dimensions.

Objects and advantages of this disclosure are further illustrated by the following non-limiting examples, but the particular materials and amounts thereof recited in these examples, as well as other conditions and details, should not be construed to unduly limit this disclosure.

### EXAMPLES

Unless otherwise noted, all parts, percentages, ratios, etc. in the Examples and the rest of the specification are by weight.

### Materials

PMMA refers to poly(methyl methacrylate) (MW=120,000 grams/mole), obtained from Aldrich Chemical Company, Milwaukee, Wis.

SR 350 trimethylolpropane trimethacrylate, containing 55-75 ppm hydroquinone and about 6 ppm MEHQ inhibitors, was obtained from Sartomer USA, LLC, Exton, Pa.

SR 368 tris(2-hydroxyethyl)isocyanurate triacrylate, containing 75-125 ppm MEHQ inhibitor, was obtained from Sartomer USA.

SR 9008 trifunctional acrylate monomer, containing 150-325 ppm MEHQ inhibitor, was obtained from Sartomer USA.

SR 9009 trifunctional methacrylate monomer, containing 160-220 ppm MEHQ inhibitor, was obtained from Sartomer USA.

IRGACURE 369 2-benzyl-2-dimethylamino-1-(4-morpholinophenyl)-butanone-1 was obtained from Ciba Specialty Chemicals, Tarrytown, N.Y.

KL68 refers to a photosensitizer having Structure I shown below synthesized as described in U.S. Pat. No. 7,265,161 (Leatherdale et al.).

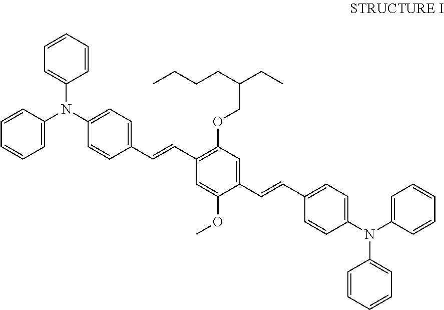 [SMILES: CCCCC(CC)COc1cc(/C=C/c2ccc(N(c3ccccc3)c3ccccc3)cc2)c(OC)cc1/C=C/c1ccc(N(c2ccccc2)c2ccccc2)cc1]

PTA refers to phenothiazine, a free-radical polymerization inhibitor.

MEHQ refers to 4-methoxyphenol, a free-radical polymerization inhibitor, available from Alfa-Aesar, Ward Hill, Mass.

TEMPO refers to 2,2,6,6-tetramethylpiperidinooxy, an inhibitor of free-radical polymerization, obtained from Sigma-Aldrich, Milwaukee, Wis.

### General Method for Preparing Acrylate and Methacrylate Photoresist Coated on Wafers:

Acrylate stock solution was prepared by mixing 30 parts by weight of PMMA, 35 parts by weight of SR 9008 trifunctional acrylate monomer, and 35 parts by weight of SR 368 alkoxylated trifunctional acrylate monomer in cyclopentanone. The resulting solution was 55 weight percent solids in cyclopentanone.

Methacrylate stock solution was prepared similar to the acrylate stock solution, except that it contained 30 parts by weight of PMMA, 35 parts by weight of SR 9009 trifunctional methacrylate monomer, and 35 parts by weight of SR 350 trimethylolpropane trimethacrylate. The resulting solution was 55 weight percent solids in cyclopentanone.

Acrylate and methacrylate photoresist solutions were prepared by adding desired amounts of photoinitiators, photosensitizer, and inhibitors to above prepared acrylate and methacrylate stock solutions, respectively. The amount of photoinitiator, photosensitizer, and inhibitors added to prepare the acrylate and methacrylate photoresist solutions used for Examples 1-10 are given hereinbelow. The desired amounts of photoinitiators and/or inhibitors were first dissolved in a minimal amount of cyclopentanone before adding them in to the acrylate or methacrylate stock solutions.

After stirring, the photoresist solutions were filtered through a 0.7-micron filter and coated on silicon wafers by spin coating. The resulting photoresist coatings had a thickness of from 5 to 15 microns.

### General Method for Determining Writing Speed Threshold and Voxel Height:

A simple two-photon writing system was used to investigate writing speed threshold and voxel height. The system was designed to cover features over a small area (about 0.1 mm²) and was equipped with an femtosecond fiber laser (model F-100, available from IMRA America, Inc., Ann Arbor, Mich.) having a center wavelength of 807 nanometers (nm) and a pulse width of 112 femtoseconds (fs), together with a laser beam power control, air objective (40×, numerical aperture 0.95), and electromagnetic shutter synchronized with the computer aided design (CAD) file according to the writing parameters. Samples were mounted on a piezosystem jena TRITOR-400 (piezosystem jena, Jena, Germany) nanopositioning X, Y, Z stage (obtained from Newport Corporation, Santa Clara, Calif.) that was driven via a computer. An Ocean Optics USB-2000 Spectrometer (obtained from Ocean Optics, Inc., Dunedin, Fla.) was used in a confocal interface detection system to accurately and precisely determine the location of the substrate-photoresist interface. The system was capable of scan rates of about 1-300 microns per second.

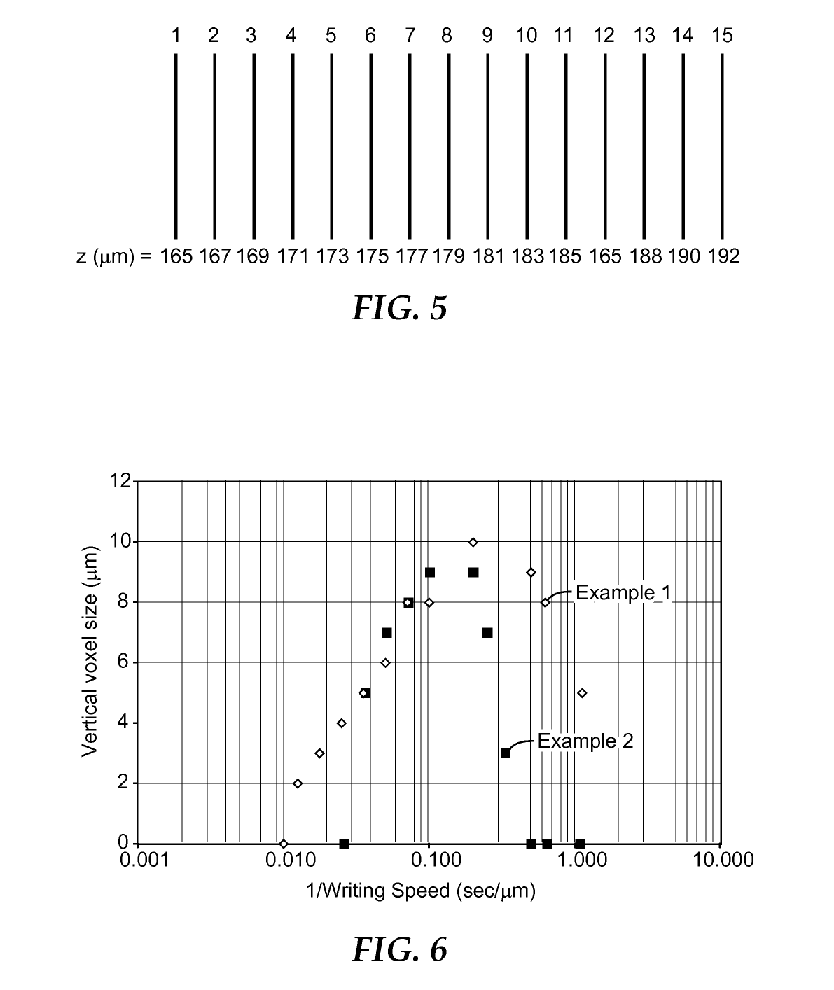

For each photoresist film of the Examples described below, the above system was employed to write different sets of two-dimensional 15-line array structures at speeds ranging from about 1 to 300 microns per second as shown in FIG. 5. In a given set, each of the 15 lines was written at the same speed, but at different Z locations with the Z_{O} being the Z location where a peak of the reflected laser beam from the interface was detected by a fiber spectrum detector. The Z_{O} typically occurred at Z=179 or 181 microns.

The 2-D line structures written as described above needed to be anchored onto the substrate in order not to be washed off by SU-8 developer (obtained from MicroChem Corp., Newton, Mass.) which dissolved uncured material after writing. The voxel size was correlated to the laser beam power, the exposed dose and the photosensitivity of the photoinitiator system used.

If the height of the sample stage was adjusted so that the laser beam coming out from the objective lens had its waist (or focused plane) right at the film/substrate interface (Z_{O}), the written line survived if the exposing dose associated with the writing speed and the dye concentration was within the threshold. If the writing speed was faster than the threshold speed, so that, the exposing dose needed was not reached to cure the film, then the written line, even if it was anchored on the surface of substrate, did not survive the development. By examining the sets with survived line(s), the threshold writing speed was determined for a given laser power and dye concentration applied to the film.

On the other hand, if the sample stage was set so that, the laser beam waist was not at the film/substrate interface, the lines written at a given writing speed survived, provided that the voxel size was big enough (i.e., the exposed dose at the interface still exceeded the threshold dose for the writing speed used and the dye concentration in the film). This provided a simple method to determine the voxel height of the laser for the particular films used for Examples 1-6 described below.

The voxel height was determined by examining how many lines (among the 15 lines written) survived the development. From the survived lines, the difference of Z for the highest Z line and the one before the lowest Z line determines the voxel height.

The contrast curves (i.e., a plot of voxel sizes versus the 1/writing speed (in seconds per micron) were then generated for photoresist compositions of each of Examples 1-7.

### Examples 1 and 2

For Example 1, the acrylate photoresist having 0.5 weight percent of IRGACURE 369 photoinitiator, prepared as described above, was used. For Example 2, the methacrylate photoresist having 1.5 weight percent of IRGACURE 369 photoinitiator, prepared as described above, was used. In Examples 1 and 2, photoresists were coated on silicon wafers as described above and the contrast curves were generated for each in FIG. 6. The Examples 1 and 2 were run in air. The laser power used was 7 and 18 milliwatts (mW) for Examples 1 and 2, respectively. Note that the use of 1.5 weight percent IRGACURE 369 photoinitiator and a laser power of 18 mW for the methacrylate photoresist of Example 2 was required to produce voxel sizes comparable to those of acrylate photoresist of Example 1. The contrast curves for both of Examples 1 and 2 showed regions where the contrast was negative (slope<0). For example 2 (i.e., methacrylate photoresist) the region with negative contrast was observed at higher scan speed and is more pronounced.

### Examples 3 and 4

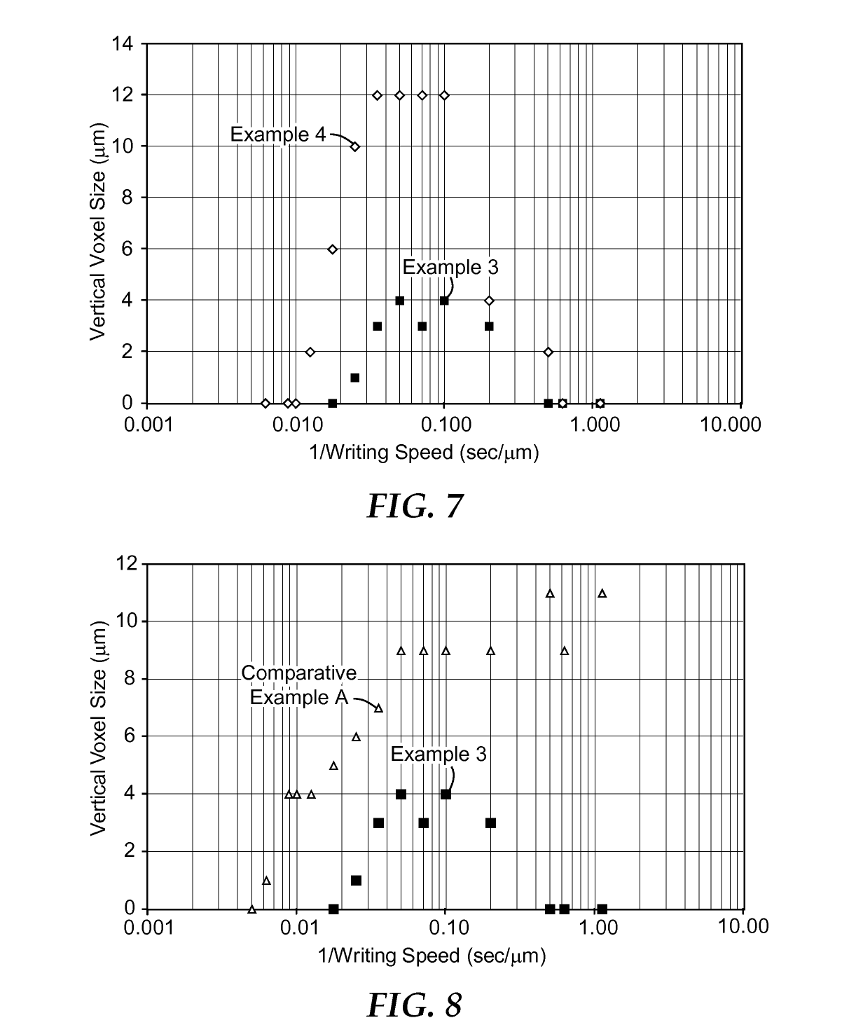

Examples 3 and 4 were run in the same manner as Examples 1 and 2, except that Example 3 used acrylate photoresist containing 0.05 weight percent of KL 68 photosensitizer and a laser power of 2.5 mW, and Example 4 used methacrylate photoresist containing 0.05 weight percent of KL 68 photosensitizer 25 mW. The contrast curves obtained for Examples 3 and 4 are shown in FIG. 7. The Examples 3 and 4 were run in air. The contrast curves for Examples 3 and 4 were similar to those of Examples 1 and 2.

### Comparative Example A

Comparative Example A was run in the same manner as Example 3, except that it was run under a nitrogen atmosphere. The contrast curves for Example 3 and Comparative Example A are shown in FIG. 8. While a region of negative contrast was observed for Example 3 (run in air), a region of negative contrast was not observed for Example 5 in nitrogen. Threshold writing speed for exposure in nitrogen was about fourfold higher (lower dose) than for exposure in air.

### Examples 5-8

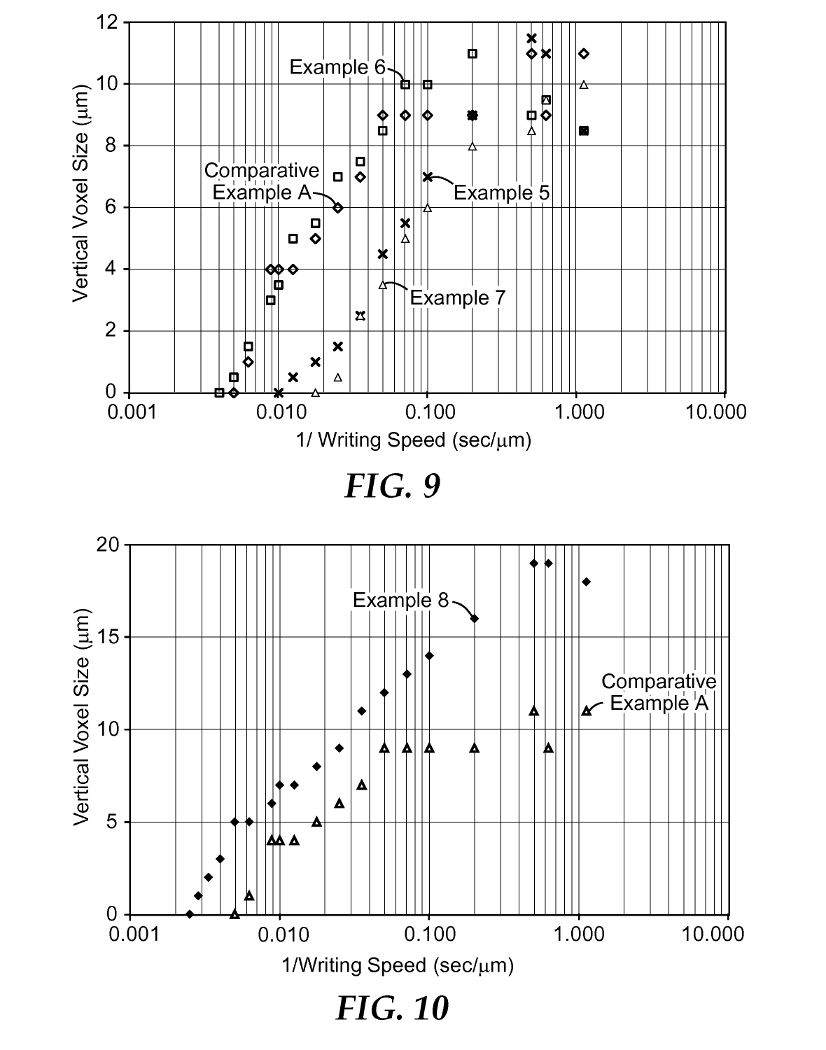

Examples 5-7 were run in the same manner as Comparative Example A, except that the photoresist compositions contained 0.1 weight percent, 0.5 weight percent and 1 weight percent of phenothiazine inhibitor, respectively. Example 8 was run in the same manner as Comparative Example A, except that the photoresist composition contained 0.25 weight percent of TEMPO. Examples 5-8 were run under a nitrogen atmosphere. The contrast curves of Comparative Example A and Examples 5-7 are shown in FIG. 9. The contrast curves of Comparative Example A and Example 8 are shown in FIG. 10.

### Example 9

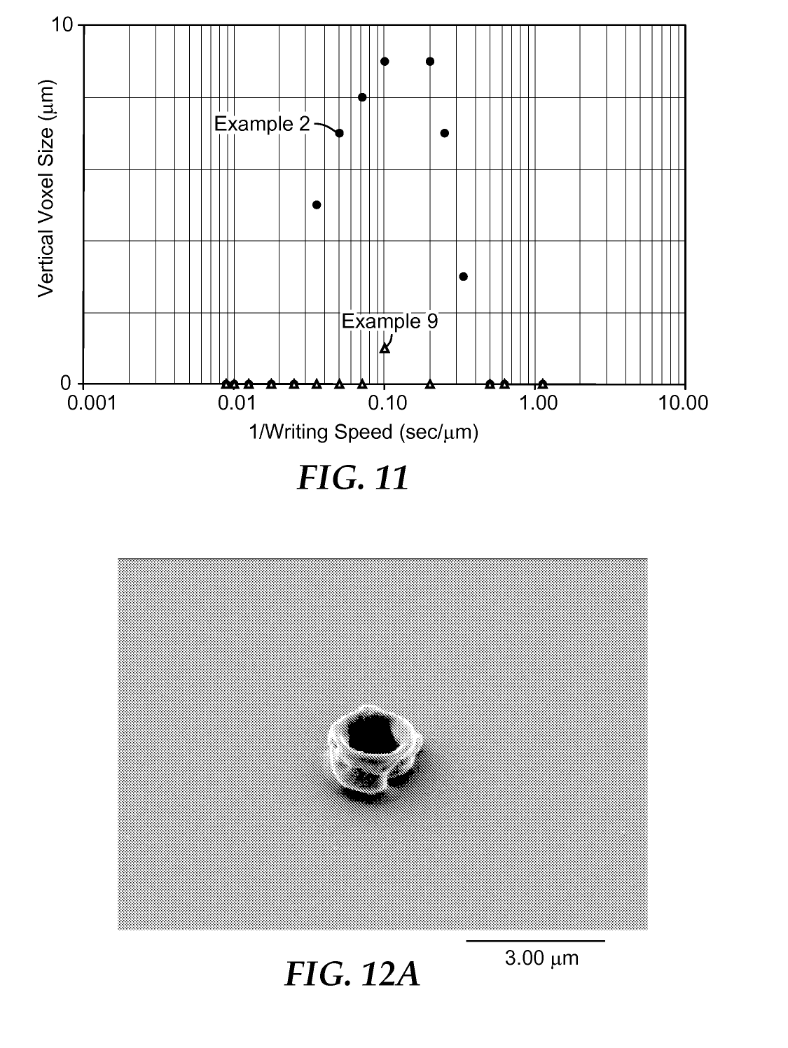

Example 9 was run in air in the same manner as Example 2, except that the photoresist contained 0.1 weight percent of MEHQ inhibitor. The contrast curves of Examples 2 and 9 are shown in FIG. 11.

### Example 10

For Example 10, a diluted methacrylate photoresist having 2.5 weight percent IRGACURE 369 photoinitiator, prepared by adding cyclopentanone into the methacrylate stock solution at 1.2 times of the weight of the stock solution, was spin-coated on a silicon substrate to get a film thickness of about 2 microns. Spot arrays written by a stationary beam under different exposure times (energy doses) at a vertical location that is at, below, and above the film-substrate interface were conducted in nitrogen and in air-dominated environments using a Gaussian and a Laguerre-Gaussian beam, respectively. Different laser powers were applied for different spot arrays. The Gaussian beam was from the laser source directly after the above-mentioned optical components and the Laguerre-Gaussian beam was obtained by directing a Gaussian beam through a VORTEX phase mask from RPC Photonics Corp., Rochester, N.Y. For the Laguerre-Gaussian beam, the intensity at the core was about 6 to 13 times lower than that in the high intensity ring region.

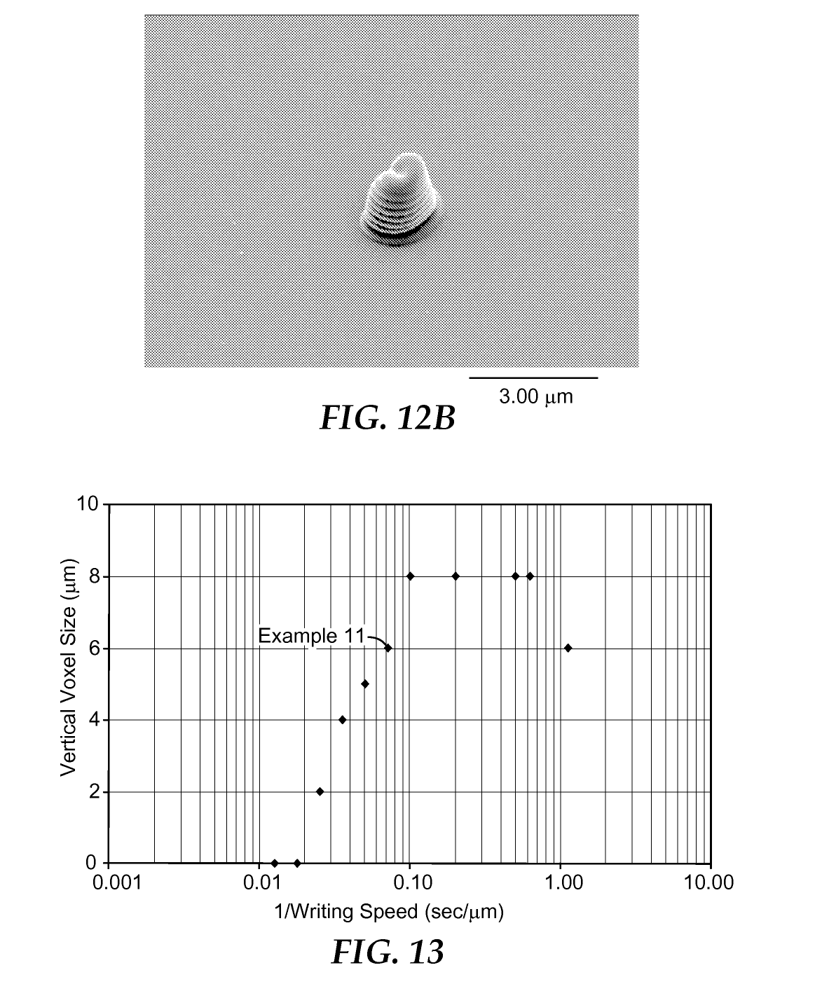

Donut-shaped spots (FIG. 12A) were clearly observed using a Gaussian beam in air. Using a Laguerre-Gaussian beam under the same kind of exposure condition (same exposed energy in air), the donut-shaped spots became much less obvious (FIG. 12B). The diameter of the hole (or an indentation) in the middle of the spot formed by a Laguerre-Gaussian beam became much smaller than that formed by a Gaussian beam. These results are counter-intuitive and are consistent with the negative contrast curve results.

In FIGS. 12A and 12B, spot arrays formed by a stationary beam exposure in air for different exposure times at a z location that was 1 μm above the interface using a laser power of 30 mW for a 2-micron thick film containing 2.5 weight percent IRGACURE 369 photoinitiator added to the methacrylate stock solution In FIG. 12A a Gaussian beam profile was used (2, 4, and 6 seconds of exposure times were used for rows 1, 2, and 3, respectively). In FIG. 12B, a Laguerre-Gaussian beam profile was used (2, 4, and 6 seconds of exposure times were used for rows 1, 2, and 3, respectively).

### Example 11

The procedure of Example 1 was repeated, except that the concentration of IRGACURE 369 photoinitiator was 1.5 weight percent, the laser power was 2.5 mW. The contrast curve for Example 11 is shown in FIG. 13.

All patents and publications referred to herein are hereby incorporated by reference in their entirety. All examples given herein are to be considered non-limiting unless otherwise indicated. Various modifications and alterations of this disclosure may be made by those skilled in the art without departing from the scope and spirit of this disclosure, and it should be understood that this disclosure is not to be unduly limited to the illustrative embodiments set forth herein.

1-28. (canceled)

29. A method comprising the steps:
a) providing a beam of light, wherein the beam of light has a cross-sectional beam profile comprising an inner region having a relatively lower intensity of the light bounded by an outer region having a relatively higher intensity of the light, and wherein the inner region and the outer region have the same temporal profile;
b) providing a photocurable composition, wherein the photocurable composition comprises a free-radically polymerizable compound, a free-radical polymerization inhibitor, and a multiphoton photoinitiator system;
c) exposing at least a portion of the photocurable composition to the beam of light such that multiphoton absorption of a portion of the light by the multiphoton photoinitiator system initiates free-radical polymerization of at least a portion of the free-radically polymerizable compound, wherein irradiating the photocurable composition with at least a portion of the inner region of the beam of light causes curing of a portion of the photocurable composition to at least a threshold level for developing, and wherein irradiating the photocurable composition with at least a portion of the outer region of the beam of light adjacent to the inner region does not cause curing of the photocurable composition to at least the threshold level for developing.

30. The method of claim 29, wherein the photocurable composition further comprises an organic polymer, and wherein the photocurable composition is substantially nonflowable.

31. The method of claim 29, wherein the outer region of the cross-sectional beam profile is substantially annular.

32. The method of claim 29, wherein the beam of light comprises a laser beam in a Gauss-Laguerre mode.

33. The method of claim 29, wherein the photocurable composition forms a layer, and wherein the layer is disposed on a substrate.

34. The method of claim 29, wherein step c) is repeated a plurality of times, and wherein each repetition the beam of light is focused at a different location within the photocurable composition according to a predetermined pattern.

35. The method of claim 34, wherein the predetermined pattern includes predetermined pattern variations in each of three dimensions.

36. The method of claim 29, further comprising developing at least a portion of the photocurable composition that is cured to at least the threshold level for developing in step c).

37. The method of claim 29, wherein the free-radical polymerization inhibitor comprises a free-radical polymerization inhibitor other than molecular oxygen.

38. The method of claim 29, wherein the free-radically polymerizable compound comprises at least two acryloyl groups.

39. A method comprising the steps:
a) providing at least one beam of light;
b) providing a photocurable composition, wherein the photocurable composition comprises a free-radically polymerizable compound, a free-radical polymerization inhibitor other than molecular oxygen, and a multiphoton photoinitiator system, wherein the free-radical polymerization inhibitor is effective in the absence of oxygen;
c) at least partially curing at least a portion of the photocurable composition by exposing it to the at least one beam of light such that multiphoton absorption of a portion of the light by the multiphoton photoinitiator system initiates free-radical polymerization of the free-radically polymerizable compound, and such that incrementally increasing exposure to the beam of light causes less curing of at least a portion of the photocurable composition exposed to the beam of light, wherein the photocurable composition is substantially free of molecular oxygen prior to said exposing the photocurable composition to the beam of light.

40. The method of claim 39, wherein, based on a total weight of the photocurable composition, the photocurable composition comprises from about 0.1 to about 0.75 percent by weight of the free-radical polymerization inhibitor.

41. The method of claim 39, wherein the free-radically polymerizable compound comprises at least two methacryloyl groups, and wherein the photocurable composition is substantially free of acrylates.

42. The method of claim 39, wherein the photocurable composition further comprises an organic polymer, and is substantially nonflowable.

43. The method of claim 39, wherein the photocurable composition forms a layer, and wherein the layer is disposed on a substrate.

44. The method of claim 39, wherein step c) is repeated a plurality of times, and wherein each repetition the beam of light is focused at a different location within the photocurable composition according to a predetermined pattern.

45. The method of claim 44, wherein the predetermined pattern includes predetermined pattern variations in each of three dimensions.

46. The method of claim 39, further comprising developing at least a portion of the photocurable composition that is cured to at least the threshold level for developing in step c).

47. A method comprising the steps:
a) providing a beam of light;
b) providing a photocurable composition, wherein the photocurable composition comprises:
a free-radically polymerizable compound,
a Type I photoinitiator, and
a free-radical polymerization inhibitor;
c) at least partially curing at least a portion of the photocurable composition by exposing it to the beam of light such that multiphoton absorption of a portion of the light by the Type I photoinitiator initiates free-radical polymerization of the free-radically polymerizable compound, and such that incrementally increasing exposure to the beam of light causes less curing of at least a portion of the photocurable composition exposed to the beam of light.

48. The method of claim 47, further comprising developing at least a portion of the photocurable composition that is cured to at least the threshold level for developing in step c).

49. The method of claim 47, wherein the free-radically polymerizable compound comprises at least one of a free-radically polymerizable acrylate or a free-radically polymerizable methacrylate.

50. The method of claim 49, wherein the free-radically polymerizable compound comprises a free-radically polymerizable methacrylate.

51. The method of claim 47, wherein the Type I photoinitiator is the Type I photoinitiator is selected from the group consisting of substituted or unsubstituted: benzoin ethers, benzyl ketals, α,α-dialkoxyacetophenones, α-hydroxyalkylphenones, α-dialkylaminoalkylphenones, acylphosphine oxides, acylphosphines, substituted derivatives thereof, and combinations thereof.

52. The method of claim 47, wherein the Type I photoinitiator comprises 2-benzyl-2-(dimethylamino)-4′-morpholinobutyrophenone.

53. The method of claim 47, wherein the photocurable composition further comprises an organic polymer, and is substantially nonflowable.

54. The method of claim 47, wherein the photocurable composition forms a layer, and wherein the layer is disposed on a substrate.

55. The method of claim 47, wherein step c) is repeated a plurality of times, and wherein each repetition the beam of light is focused at a different location within the photocurable composition according to a predetermined pattern.

56. The method of claim 55, wherein the predetermined pattern includes predetermined pattern variations in each of three dimensions.
